(19) United States
(12) Patent Application Publication
(10) Pub. No.: US 2014/0374877 A1
(43) Pub. Date: Dec. 25, 2014

(54) Integrated Circuits With On-Die Decoupling Capacitors

(71) Applicant: Altera Corporation, San Jose, CA (US)

(72) Inventors: Kyung Suk Oh, Cupertino, CA (US); Bonnie Wang, Cupertino, CA (US); Hong Shi, Fremont, CA (US); Hui Liu, Dublin, CA (US); Sergey Shumarayev, Los Altos Hills, CA (US); Sunitha Chandra, Cupertino, CA (US); Weiqi Ding, Fremont, CA (US); Kundan Chand, Sunnyvale, CA (US)

(73) Assignee: Altera Corporation, San Jose, CA (US)

(21) Appl. No.: 13/924,024

(22) Filed: Jun. 21, 2013

(51) Int. Cl. H01L 23/522; H01L 21/768

(52) U.S. Cl. CPC H01L 23/5223; H01L 21/7687
USPC 257/532; 438/107

(57) ABSTRACT

An integrated circuit includes a decoupling capacitor and an internal circuit. The decoupling capacitor is coupled to a first external terminal of the integrated circuit. The internal circuit in the integrated circuit is coupled to a second external terminal of the integrated circuit. The decoupling capacitor is coupled to provide supply voltage current to the internal circuit through the first and the second external terminals and through external conductors. The external conductors are outside the integrated circuit.

### FIELD OF THE DISCLOSURE

The present disclosure relates to electronic circuits, and more particularly, to integrated circuits with on-die decoupling capacitors.

### BACKGROUND

Many integrated circuit designs require power supply lines to supply stable supply voltages for integrated circuits operating at high data rates and high clock signal frequencies. Decoupling capacitors are often used to help provide more stable power supply voltages to circuits in integrated circuits. A decoupling capacitor shunts high frequency noise on a direct current (DC) supply voltage line to a ground supply line, thereby preventing noise from reaching circuits on an integrated circuit that receive the supply voltage. Decoupling capacitance acts as a store of charge that provides current to maintain a stable supply voltage during circuit operation.

### BRIEF SUMMARY

According to some embodiments, an integrated circuit includes a decoupling capacitor and an internal circuit. The decoupling capacitor is coupled to a first external terminal of the integrated circuit. The internal circuit in the integrated circuit is coupled to a second external terminal of the integrated circuit. The decoupling capacitor is coupled to provide supply voltage current to the internal circuit through the first and the second external terminals and through external conductors. The external conductors are outside the integrated circuit.

According to other embodiments, a system includes first and second integrated circuits. The first integrated circuit has a decoupling capacitor. The second integrated circuit has an internal circuit. In one embodiment, the first and the second integrated circuits are in the same packaging house such as an organic package substrate, silicon interposer substrate, or multi-chip module (MCM). In another embodiment, the first and the second integrated circuits are vertically stacked dies that are coupled together. The decoupling capacitor is coupled to the internal circuit through conductive material in a through-silicon via in the second integrated circuit.

Various objects, features, and advantages of the present invention will become apparent upon consideration of the following detailed description and the accompanying figures.

### BRIEF DESCRIPTION OF THE DRAWINGS

FIG. 1 illustrates a top down layout view of an example of an integrated circuit that includes on-die decoupling capacitors, according to an embodiment of the present invention.

FIG. 2 illustrates cross-sectional side views of a portion of the integrated circuit shown in FIG. 1 and a medium that has multiple layers, according to an embodiment of the present invention.

FIG. 3 illustrates a bottom up layout view of a portion of the integrated circuit shown in FIG. 1, according to an embodiment of the present invention.

FIG. 4 illustrates a bottom up layout view of an example of an on-die decoupling capacitor, according to an embodiment of the present invention.

FIG. 5 illustrates a bottom up layout view of another example of an on-die decoupling capacitor, according to an alternative embodiment of the present invention.

FIG. 6 illustrates cross-sectional side views of two integrated circuits that are coupled together through a medium having multiple layers, according to an embodiment of the present invention.

FIG. 7 illustrates cross-sectional side views of two stacked integrated circuits that are coupled together through solder bumps, according to an embodiment of the present invention.

FIG. 8 is a simplified partial block diagram of a field programmable gate array (FPGA) that can include embodiments of the present invention.

FIG. 9 shows a block diagram of an exemplary digital system that can embody techniques of the present invention.

### DETAILED DESCRIPTION

Integrated circuits typically receive power from supply voltages. A supply voltage may be generated by a voltage regulator module (VRM) and provided to an integrated circuit. The integrated circuit and the VRM may be coupled to the same circuit board. The supply voltage is provided from the VRM through the circuit board to the integrated circuit. The integrated circuit may be housed in a package.

A supply voltage that is at a constant or nearly constant voltage is desired for optimal performance of an integrated circuit. The amount of current drawn from a supply voltage may vary during the operation of an integrated circuit. Capacitors are often connected to a circuit board to reduce fluctuations in a supply voltage that is provided from a VRM to an integrated circuit through the circuit board. The capacitors coupled to the circuit board may include bulk capacitors and surface mount capacitors. However, the inductance between the integrated circuit and the capacitors coupled to the circuit board is often large enough to generate significant fluctuations in the supply voltage in response to variations in the current drawn from the integrated circuit during operation.

During the operation of an integrated circuit, power usage of the integrated circuit may vary. For example, the integrated circuit may draw additional supply voltage current when there is a change in the state of an internal circuit. Changes in the supply voltage current consumption of the integrated circuit causes current fluctuations and creates unwanted supply voltage noise. A decoupling capacitor can be used to maintain a more constant supply voltage received by the integrated circuit. The decoupling capacitor serves as a local energy storage reserve that provides supply voltage current for circuits in the integrated circuit. A decoupling capacitor can accommodate changing power demand during circuit operation. A decoupling capacitor reduces noise in the supply voltage.

An on-package decoupling (OPD) capacitor can provide decoupling capacitance to circuits in an integrated circuit that is housed in the same package as the OPD capacitor. The OPD capacitor is coupled to the integrated circuit through conductors in the package. However, if the conductors in the package have a significant amount of inductance, then the OPD capacitor may not provide a supply voltage to the integrated circuit that is stable enough to meet the operating specifications of circuits in the integrated circuit.

An integrated circuit may have an on-die decoupling capacitor (ODC) that is used to reduce noise-induced variations in a supply voltage. An on-die decoupling capacitor and the circuits that draw current from the supply voltage are in the same integrated circuit die. Supply voltage current is provided from the on-die decoupling capacitor to the circuits through conductors that are located entirely within the integrated circuit.

However, some integrated circuit designs may not have enough die area to locate an on-die decoupling capacitor near the circuits that receive the supply voltage. If the on-die decoupling capacitor is a substantial distance away from the circuits receiving the supply voltage, a low resistance connection on the integrated circuit between the on-die decoupling capacitor and the circuits may use a substantial amount of die area, which is undesirable. In some integrated circuits, an extra metal layer may not be available for a low resistance connection between an on-die decoupling capacitor and the circuits that receive the supply voltage.

According to some embodiments, an on-die decoupling capacitor in an integrated circuit provides supply voltage current to one or more circuits in the integrated circuit. The on-die decoupling capacitor and the circuits that receive the supply voltage current from the on-die decoupling capacitor are in the same integrated circuit. The on-die decoupling capacitor is coupled to the circuits through external conductors that are outside the integrated circuit. The supply voltage current is provided from the on-die decoupling capacitor to the circuits through the external conductors. The external conductors may be, for example, conductors in a package, conductors in an interposer, conductors in a redistribution layer, or conductors in a through-silicon via (TSV) in another integrated circuit. The supply voltage may, for example, be provided to the on-die decoupling capacitor from a voltage regulator module (VRM) that is outside the integrated circuit. The external conductors can be reconfigured to couple the on-die decoupling capacitor to different circuits in the integrated circuit, without redesigning the integrated circuit.

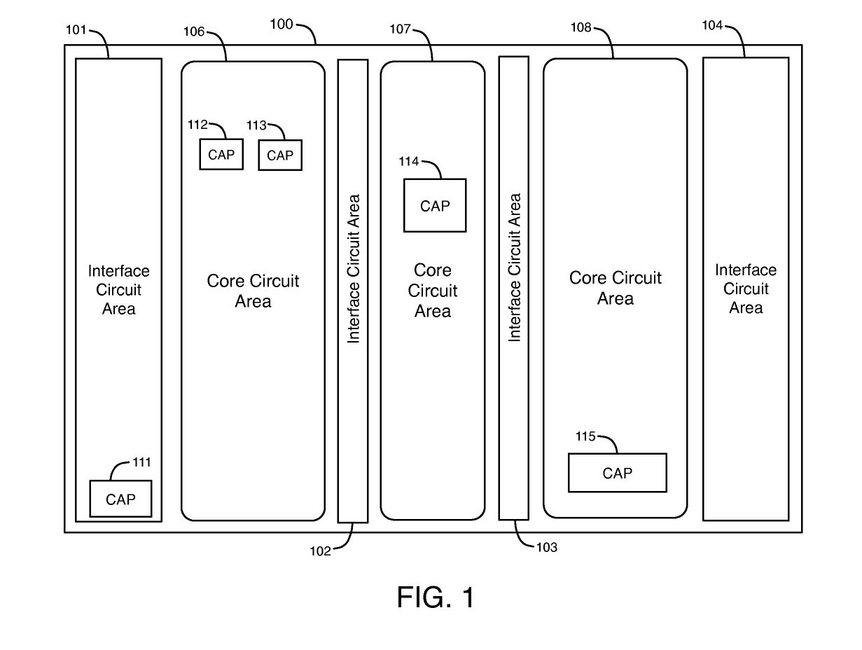

FIG. 1 illustrates a top down layout view of an example of an integrated circuit 100 that includes on-die decoupling capacitors, according to an embodiment of the present invention. Integrated circuit 100 includes four interface circuit areas 101-104 and three core circuit areas 106-108. Each of the interface circuit areas 101-104 includes one or more interface circuits that transmit and receive signals between one or more devices that are outside of integrated circuit 100.

Each of the core circuit areas 106-108 includes circuits that perform the intended functions of integrated circuit 100. Core circuit areas 106-108 typically do not include interface circuits that communicate directly with devices outside of integrated circuit 100. If core circuit areas 106-108 do not include interface circuits, core circuit areas 106-108 may be referred to as non-interface circuit areas.

Integrated circuit 100 may include digital circuits, analog circuits, or both digital and analog circuits. Integrated circuit 100 may be an application specific integrated circuit (ASIC) or a programmable integrated circuit. If integrated circuit 100 is a programmable logic integrated circuit, each of the core circuit areas 106-108 may include arrays of programmable logic circuits.

Integrated circuit 100 also includes on-die decoupling capacitors 111-115. On-die decoupling capacitor 111 is in interface circuit area 101. On-die decoupling capacitors 112-113 are in core circuit area 106. On-die decoupling capacitor 114 is in core area 107. On-die decoupling capacitor 115 is in core circuit area 108. According to various embodiments, the on-die decoupling capacitors in integrated circuit 100 may be any suitable type of capacitors or a combination of different types of capacitors. For example, on-die decoupling capacitors 111-115 may be Metal-Insulator-Metal (MIM) capacitors, metal-oxide-metal (MOM) capacitors, gate capacitors, or a combination of these or other types of capacitors. According to various embodiments, the on-die decoupling capacitors in integrated circuit 100 may be multiple different shapes, such as a square shape, a rectangular shape, a circular shape, an oval shape, an L-shape, or an irregular shape.

Each of the on-die decoupling capacitors 111-115 receives a direct current (DC) voltage from a source that is outside of integrated circuit 100. Two or more of on-die decoupling capacitors 111-115 may receive the same DC voltage. Two or more of on-die decoupling capacitors 111-115 may receive different DC voltages. Each DC voltage is provided from the on-die decoupling capacitor to respective circuits on integrated circuit 100 through external conductors that are outside integrated circuit 100. The external conductors may be, for example, in a package, in an interposer, in a redistribution layer, or in another integrated circuit.

The voltages provided to capacitors 111-115 may be any types of DC voltages, such as supply voltages. As an example, both of on-die decoupling capacitors 112-113 may receive a first supply voltage VCCIO1. Supply voltage VCCIO1 is provided to circuits in one or more of interface circuit areas 101-104. As another example, on-die decoupling capacitor 111 may receive a second supply voltage VCCIO2. Supply voltage VCCIO2 is provided to circuits in one or more of interface circuit areas 101-104. As yet another example, on-die decoupling capacitors 114-115 may receive a third supply voltage VCCCORE. Supply voltage VCCCORE is provided to circuits in core circuit areas 106-108.

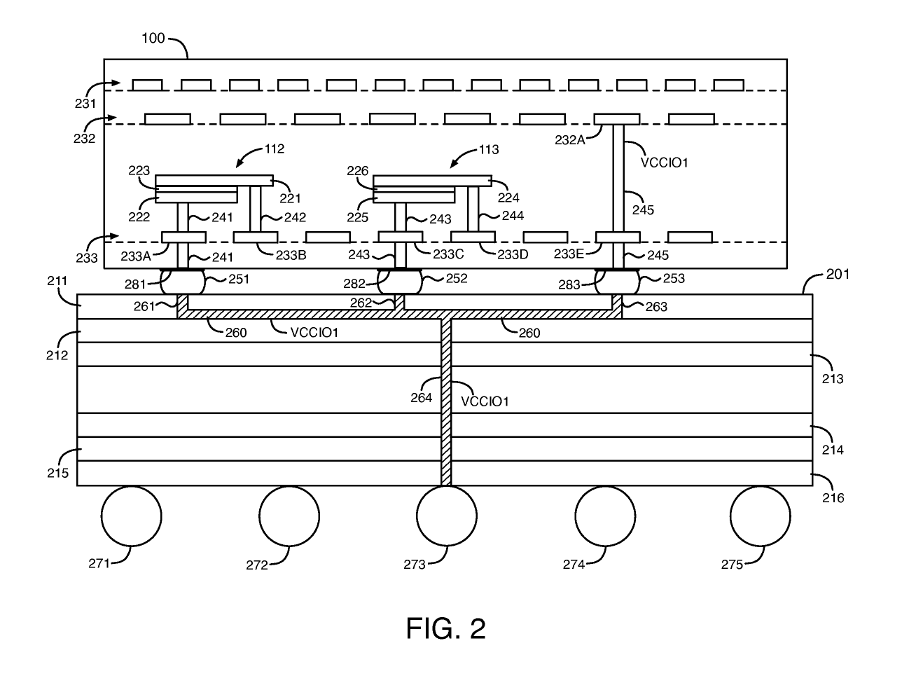

FIG. 2 illustrates cross-sectional side views of a portion of the integrated circuit 100 shown in FIG. 1 and a medium 201 that has multiple layers, according to an embodiment of the present invention. In the embodiment of FIG. 2, integrated circuit 100 has multiple layers, including patterned layers 231-233. Integrated circuit 100 has other layers in addition to layers 231-233. The layers of integrated circuit 100 may include, for example, conductive layers, semiconductor layers, and insulating layers. The layers of integrated circuit 100 may be patterned during fabrication. Integrated circuit 100 also has vias, including vias 241-245. Vias 241-245 are filled with conductive material. As an example, the conductors and conductive material described herein may include metal. Integrated circuit 100 also has external terminals (i.e., pads) 281-283. External terminals 281-283 are conductive regions on the bottom (or top) surface of integrated circuit 100.

Medium 201 has multiple layers, including layers 211-216. Medium 201 has one or more conductive layers and one or more insulating layers. In the example of FIG. 2, layer 211 is a conductive layer, and layer 212 is an insulating layer. Medium 201 is coupled to integrated circuit 100 through solder bumps, including solder bumps 251-253. Medium 201 may be, for example, a package for housing integrated circuit 100, an interposer coupled to integrated circuit 100, redistribution layers coupled to integrated circuit 100, or another integrated circuit coupled to integrated circuit 100.

Two of the on-die decoupling capacitors 112-113 in integrated circuit 100 that are shown in FIG. 1 are also shown in cross-sectional side view in FIG. 2. Capacitors 112-113 may be, for example, MIM capacitors. According to other embodiments, capacitors 112-113 may be other types of capacitors, such as gate capacitors or MOM capacitors.

Capacitor 112 includes electrically conductive regions 221-222 and dielectric region 223. Dielectric region 223 is in between conductive regions 221 and 222. Conductive region 222 is coupled to solder bump 251 through the conductive material in via 241 and through external terminal 281. The conductive material in via 241 is coupled to conductive region 233A in layer 233. Conductive region 222 of capacitor 112 may be coupled to one or more other decoupling capacitors or other circuits in integrated circuit 100 through conductive region 233A. Conductive region 221 is coupled to conductive region 233B in layer 233 through the conductive material in via 242. Conductive region 221 of capacitor 112 is coupled to ground through conductive region 233B.

Capacitor 113 includes electrically conductive regions 224-225 and dielectric region 226. Dielectric region 226 is in between conductive regions 224 and 225. Conductive region 225 is coupled to solder bump 252 through the conductive material in via 243 and through external terminal 282. The conductive material in via 243 is coupled to conductive region 233C in layer 233. Conductive region 225 of capacitor 113 may be coupled to one or more other decoupling capacitors or other circuits in integrated circuit 100 through conductive region 233C. Conductive region 224 is coupled to conductive region 233D in layer 233 through the conductive material in via 244. Conductive region 224 of capacitor 113 is coupled to ground through conductive region 233D.

Conductive layer 211 of medium 201 includes a conductor 260 and vias 261-263. Medium 201 also includes via 264. Vias 261-264 are filled with conductive material. Conductor 260 and the conductive material in vias 261-264 are external conductors that are outside integrated circuit 100. Conductor 260 is coupled to solder bumps 251-253 through the conductive material in vias 261-263, respectively. Conductor 260 and the conductive material in vias 261-264 are indicated by diagonal lines in FIG. 2.

Capacitor 112 is coupled to conductor 260 through solder bump 251, the conductive material in vias 241 and 261, and external terminal 281 of integrated circuit 100. Capacitor 113 is coupled to conductor 260 through solder bump 252, the conductive material in vias 243 and 262, and external terminal 282 of integrated circuit 100. Conductor 260 is also coupled to solder bump 253 through the conductive material in via 263. Solder bump 253 is coupled to the conductive material in via 245 through external terminal 283. Region 232A of layer 232 is coupled to the conductive material in via 245. Capacitors 112-113 are coupled to region 232A through the conductive material in vias 241, 243, and 245, solder bumps 251-253, external terminals 281-283, and external conductors in medium 201, which include conductor 260 and the conductive material in vias 261-263.

Region 232A may be, for example, a conductive region or a semiconductor region that is part of a circuit within integrated circuit 100. Region 232A is part of a circuit located in interface circuit area 102 or in interface circuit area 103. Region 232A may be, for example, part of a transistor or a passive circuit, such as a resistor or capacitor. The conductive material in via 245 is also coupled to conductive region 233E in layer 233. Conductor 260 may be coupled to other circuits in interface circuit areas 102-103 or in other parts of integrated circuit 100 through conductive region 233E.

Medium 201 is connected to conductive balls 271-275. Conductive balls 271-275 may be connected to a circuit board (not shown). Conductor 260 is coupled to the conductive material in via 264. Conductor 260 is coupled to conductive ball 273 through the conductive material in via 264.

A supply voltage VCCIO1 is provided from a VRM or other source through the circuit board, conductive ball 273, and the conductive material in via 264 to conductor 260. The supply voltage VCCIO1 is provided through conductor 260, the conductive material in vias 261-262, solder bumps 251-252, external terminals 281-282, and the conductive material in vias 241 and 243 to conductive regions 222 and 225 in capacitors 112 and 113, respectively. Decoupling capacitors 112-113 reduce noise-induced fluctuations in the supply voltage VCCIO1. Supply voltage VCCIO1 may also be provided to other decoupling capacitors in integrated circuit 100. The supply voltage VCCIO1 is also provided through conductor 260, the conductive material in via 263, solder bump 253, external terminal 283, and the conductive material in via 245 to region 232A and to other circuits in integrated circuit 100 through region 233E or through other solder bumps.

Conductive region 221 in capacitor 112 is coupled to receive a ground voltage through the conductive material in via 242 and conductive region 233B. Conductive region 224 in capacitor 113 is coupled to receive the ground voltage through the conductive material in via 244 and conductive region 233D. Conductive regions 233B and 233D are coupled together through conductive regions not shown in FIG. 2. The ground voltage may also be provided to other decoupling capacitors in integrated circuit 100.

The conductors on the circuit board that couple the VRM to medium 201 typically have a significant inductance. The conductors that couple capacitors 112-113 to the circuits in integrated circuit 100 receiving supply voltage VCCIO1 include conductor 260, solder bumps 251-253, external terminals 281-283, and the conductive material in vias 241, 243, 245, and 261-263. The conductive path from capacitors 112-113 through conductor 260 to the circuits in integrated circuit 100 that receive supply voltage VCCIO1 typically has a much lower inductance than the conductive path that provides supply voltage VCCIO1 from the VRM to conductor 260.

Decoupling capacitors 112-113 provide supply voltage current for supply voltage VCCIO1 to the circuits in integrated circuit 100 that receive supply voltage VCCIO1. Because conductor 260, solder bumps 251-253, external terminals 281-283, and the conductive material in vias 241, 243, 245 and 261-263 have a low inductance, the decoupling capacitors 112-113 provide a rapidly changing current to circuits in integrated circuit 100. This supply voltage current from capacitors 112-113 reduces variations in the supply voltage VCCIO1 received by the circuits in integrated circuit 100.

In some embodiments, decoupling capacitors 111 and 114-115 are coupled to circuits in respective areas of integrated circuit 100 through external conductors in medium 201. The circuits in integrated circuit 100 that decoupling capacitors 111-115 are coupled to can be changed by changing the external conductors, without changing or redesigning integrated circuit 100. For example, integrated circuit 100 can be disconnected from medium 201 and then connected to a different package or interposer having external conductors that couple decoupling capacitors 112-113 to circuits in core area 106 or to circuits in interface circuit area 101.

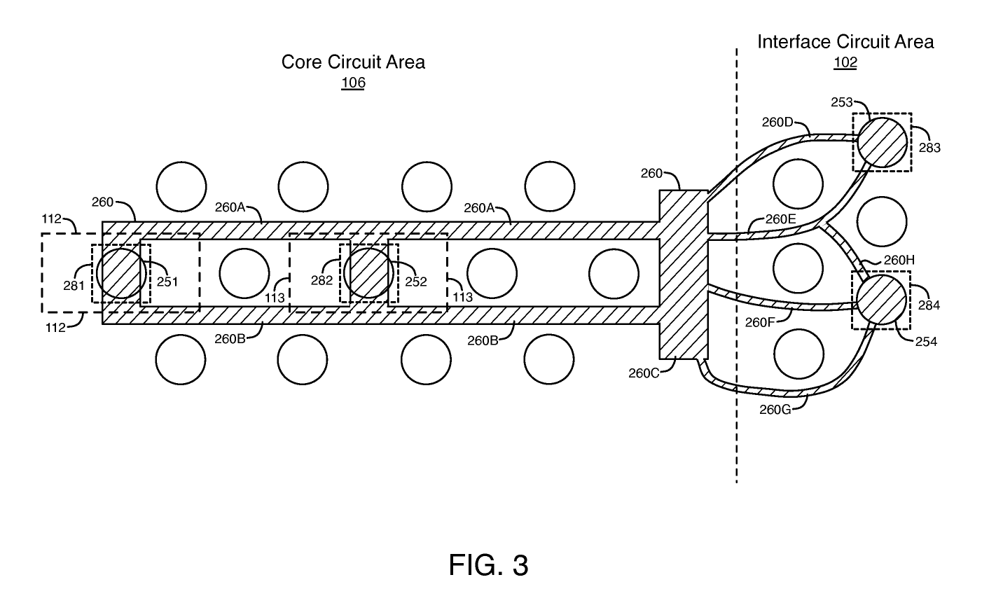

FIG. 3 illustrates a bottom up layout view of a portion of the integrated circuit 100 shown in FIG. 1, according to an embodiment of the present invention. FIG. 3 illustrates a portion of the core circuit area 106 and a portion of interface circuit area 102 of integrated circuit 100. FIG. 3 also illustrates 19 solder bumps, including solder bumps 251-254. The solder bumps are shown as 19 circles in FIG. 3. Integrated circuit 100 is coupled to medium 201 through the solder bumps shown in FIG. 3 and through other solder bumps that are not shown in FIG. 3.

FIG. 3 also illustrates conductor 260 and capacitors 112-113. Capacitors 112-113 are in core area 106. In the embodiment of FIG. 3, capacitors 112 and 113 are rectangular. Capacitors 112 and 113 are indicated by dotted rectangles in FIG. 3. FIG. 3 also illustrates external terminals 281-284 of integrated circuit 100. External terminal 284 is a conductive region on the bottom surface of integrated circuit 100. External terminals 281-284 are indicated by dotted squares in FIG. 3. Solder bumps 251-254 are coupled to external terminals 281-284, respectively.

Conductor 260 and solder bumps 253 and 254 are indicated by diagonal lines in FIG. 3. In the embodiment of FIG. 3, conductor 260 includes regions 260A-260H. The solder bumps shown in FIG. 3 are arranged in 3 rows. Region 260A is a linear stripe between the first and second rows of solder bumps. Region 260B is a linear stripe between the second and third rows of solder bumps. One region of conductor 260 that connects regions 260A and 260B underlies and connects to solder bump 251. Another region of conductor 260 that connects regions 260A and 260B underlies and connects to solder bump 252. Solder bumps 251-252 are coupled to capacitors 112-113 through external terminals 281-282, respectively.

A supply voltage VCCIO1 is provided to capacitors 112-113 through conductor 260 and solder bumps 251-252, respectively. Conductor 260 also includes a rectangular region 260C. Conductor 260 only lies under the solder bumps that conductor 260 is coupled to. Conductor 260 does not lie under any of the other solder bumps shown in FIG. 3, which reduces parasitic capacitive coupling.

In the embodiment of FIG. 3, solder bumps 253 and 254 are under interface circuit area 102. Regions 260D-260E connect region 260C to solder bump 253. Regions 260E-260H connect region 260C to solder bump 254. Solder bump 253 is coupled to conductive material in via 245 through external terminal 283, as described above with respect to FIG. 2. Supply voltage VCCIO1 is provided through conductor 260 to circuits in interface circuit area 102 through solder bumps 253-254 and external terminals 283-284. Solder bump 254 is coupled to circuits in integrated circuit 100 that receive supply voltage VCCIO1 through external terminal 284. Supply voltage VCCIO1 may also be provided through conductor 260 to circuits in interface circuit area 103 through additional solder bumps (not shown).

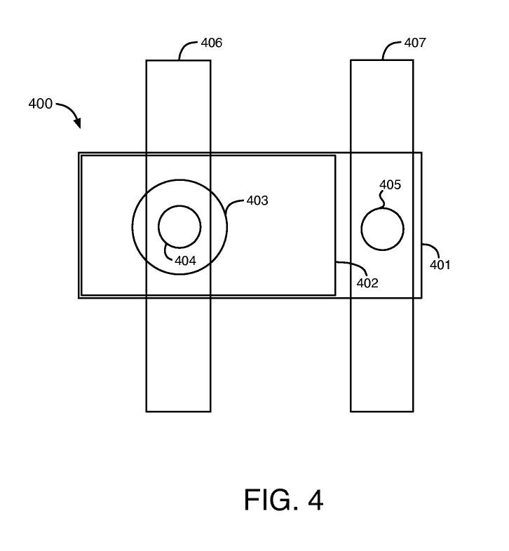

FIG. 4 illustrates a bottom up layout view of an example of a decoupling capacitor 400, according to an embodiment of the present invention. Decoupling capacitor 400 is an example of each of the decoupling capacitors 112 and 113 shown in FIGS. 1-3. In an embodiment, each of capacitors 112 and 113 has the structure of capacitor 400 shown in FIG. 4. Decoupling capacitor 400 may be an example of other decoupling capacitors in integrated circuit 100.

Capacitor 400 includes conductive regions 401-402 and a dielectric layer (not shown) in between conductive regions 401-402. Conductive regions 401-402 form the conductive plates of capacitor 400. FIG. 4 also illustrates solder bump 403, vias 404-405 that are filled with conductive material, and conductive regions 406-407.

Conductive region 402 is coupled to conductive region 406 through conductive material in via 404. Conductive region 402 is coupled to solder bump 403 through the conductive material in via 404. Conductive region 402 receives a supply voltage through solder bump 403 and via 404. Conductive region 401 is coupled to conductive region 407 through conductive material in via 405. Conductive region 401 receives a ground voltage through conductive region 407 and via 405. Only portions of conductive regions 406-407 are shown in FIG. 4. Conductive regions 406-407 are typically coupled to other circuits on the same integrated circuit.

In an embodiment, capacitor 400 is capacitor 112 shown in FIGS. 1-3. In this embodiment, conductive regions 401-402 are conductive regions 221-222, respectively, shown in FIG. 2, and conductive regions 406-407 are conductive regions 233A-233B, respectively, shown in FIG. 2. Also, via 404 is via 241 in FIG. 2, via 405 is via 242 in FIG. 2, and solder bump 403 is solder bump 251 in FIG. 2.

In another embodiment, capacitor 400 is capacitor 113 shown in FIGS. 1-3. In this embodiment, conductive regions 401-402 are conductive regions 224-225, respectively, shown in FIG. 2, and conductive regions 406-407 are conductive regions 233C-233D, respectively, shown in FIG. 2. Also, via 404 is via 243 in FIG. 2, via 405 is via 244 in FIG. 2, and solder bump 403 is solder bump 252 in FIG. 2.

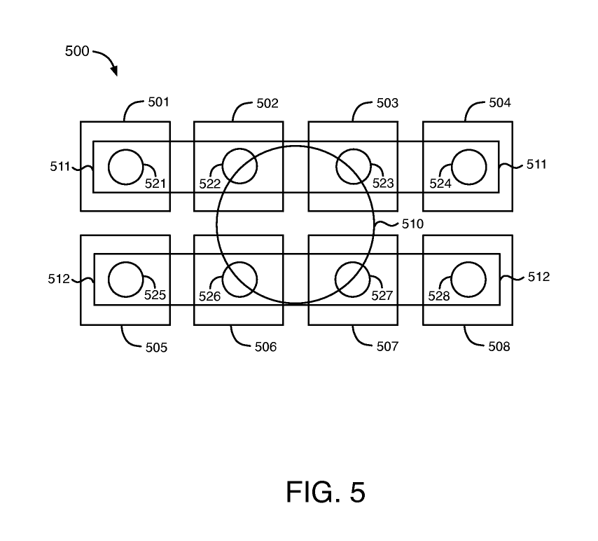

FIG. 5 illustrates a bottom up layout view of an example of a decoupling capacitor 500, according to an embodiment of the present invention. Decoupling capacitor 500 is an example of each of the decoupling capacitors 112 and 113, as shown in FIGS. 1 and 3. In an embodiment, each of capacitors 112 and 113 has the structure of capacitor 500 shown in FIG. 5. Decoupling capacitor 500 may be an example of other decoupling capacitors in integrated circuit 100. As an example, decoupling capacitor 500 is a MIM capacitor.

Decoupling capacitor 500 includes eight conductive islands 501-508, which may be MIM islands. Islands 501-508 are patterned regions formed from a layer of conductive material. Decoupling capacitor 500 also includes conductive regions 511-512. In an exemplary embodiment, conductive islands 501-508 are formed from a first patterned conductive layer (e.g., a first metal layer) in integrated circuit 100, and regions 511-512 are formed from a second patterned conductive layer (e.g., a second metal layer) in integrated circuit 100.

Decoupling capacitor 500 also includes 8 vias 521-528. Each of the vias 521-528 is filled with conductive material. Conductive region 511 is coupled to each of conductive islands 501-504 through the conductive material in vias 521-524, respectively. Conductive region 512 is coupled to each of conductive islands 505-508 through the conductive material in vias 525-528, respectively.

Conductive regions 511-512 may, for example, be coupled to solder bump 510 through additional vias (not shown). Alternatively, conductive regions 511-512 may be external terminals on the surface of the integrated circuit and directly coupled to solder bump 510. Solder bump 510 may be, for example, solder bump 251 or 252 in the respective decoupling capacitor 112 or 113.

Conductive islands 501-508 form one conductive plate of the decoupling capacitor 500 that receives a supply voltage through bump 510, conductive regions 511-512, and vias 521-528. Capacitor 500 also includes a second conductive plate (not shown) that receives a ground voltage and a dielectric region between the two conductive plates.

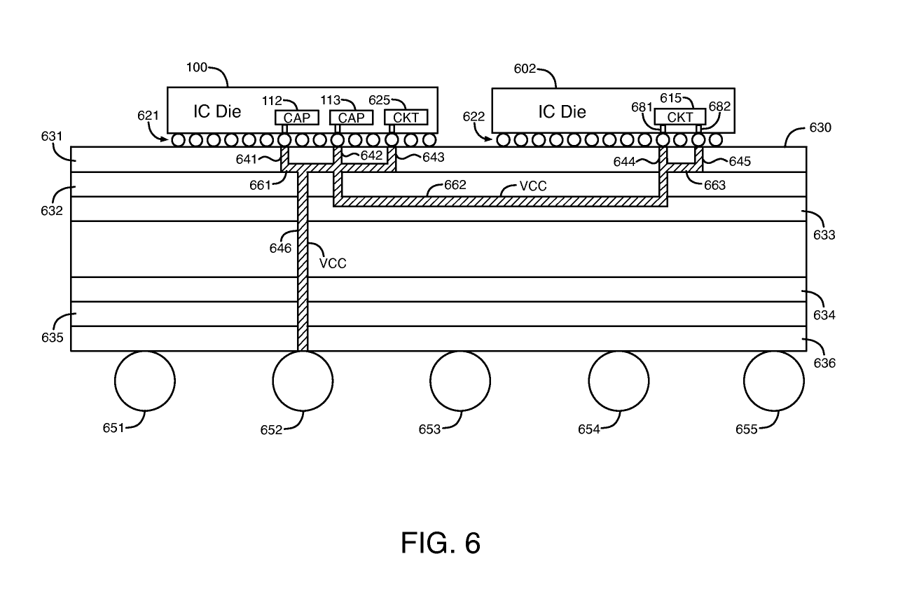

According to another embodiment, an on-die decoupling capacitor in a first integrated circuit provides decoupling capacitance for a voltage provided to a second integrated circuit. The first integrated circuit also has other circuits in addition to the on-die decoupling capacitor. Integrated circuit 100 is an example of the first integrated circuit, which includes decoupling capacitors 111-115 and other circuits in areas 101-104 and 106-108. The on-die decoupling capacitor in the first integrated circuit is coupled to the second integrated circuit through external conductors in a medium. The medium may be, for example, a package, an interposer, or a redistribution layer. FIG. 6 illustrates an example of this embodiment.

FIG. 6 illustrates cross-sectional side views of two integrated circuits that are coupled together through a medium having multiple layers, according to an embodiment of the present invention. FIG. 6 illustrates two separate integrated circuits (i.e., IC dies) 100 and 602 and a medium 630. Integrated circuit 100 is also shown in FIGS. 1-3.

Integrated circuit 602 may be any type of integrated circuit. Integrated circuit 602 may be an application specific integrated circuit, a programmable integrated circuit, or any combination thereof. Integrated circuit 602 may include digital circuits, analog circuits, or a combination of digital and analog circuits. Integrated circuit 602 includes circuit (CKT) 615 and other circuits not shown in FIG. 6. Circuit 615 is coupled to medium 630 through conductive material in vias 681-682 and two of solder bumps 622.

Medium 630 has multiple layers, including layers 631-636. Medium 630 may be, for example, a package, an interposer, redistribution layers, or a third integrated circuit. Medium 630 has one or more conductive layers and one or more insulating layers. In the example of FIG. 6, layers 631 and 633 are conductive layers, and layer 632 is an insulating layer. Medium 630 is coupled to integrated circuit 100 through solder bumps 621 and to integrated circuit 602 through solder bumps 622.

Medium 630 includes vias 641-646 and conductors 661-663. Vias 641-646 are filled with conductive material. Conductors 661 and 663 are in conductive layer 631. Conductor 662 is in conductive layer 633. Conductors 661-663 and the conductive material in vias 641-646 are indicated by diagonal lines in FIG. 6. Medium 630 is coupled to a circuit board (not shown) through conductive balls 651-655.

Capacitors 112 and 113 are coupled together through two of solder bumps 621 and external conductors in layer 631 of medium 630, including conductor 661 and the conductive material in vias 641-642. Capacitors 112-113 are coupled to a circuit 625 in integrated circuit 100 through three of solder bumps 621, the conductive material in vias 641-643, and conductor 661.

A supply voltage VCC is provided from an external VRM through conductive ball 652, the conductive material in via 646, conductor 661, the conductive material in vias 641-642, and two of solder bumps 621 to capacitors 112-113. Supply voltage VCC is also provided to circuit 625 through conductive ball 652, the conductive material in via 646, conductor 661, the conductive material in via 643, one of solder bumps 621, and a via in integrated circuit 100. Current for supply voltage VCC is provided from capacitors 112-113 to circuits 615 and 625 through external conductors in medium 630. Current for supply voltage VCC is provided from capacitors 112-113 to circuit 615 in integrated circuit 602 through the conductive material in via 641, conductor 661, the conductive material in via 642, conductor 662, the conductive material in via 644, conductor 663, the conductive material in via 645, two of solder bumps 622, and the conductive material in vias 681-682.

Thus, capacitors 112-113 are coupled to circuit 615 through these external conductors in medium 630. In the embodiment of FIG. 6, capacitors 112-113 in a first integrated circuit 100 provide decoupling capacitance to a circuit 615 in a second integrated circuit 602 through external conductors in medium 630. Decoupling capacitors 112-113 provide supply voltage current to circuit 615 to reduce variations in the supply voltage VCC received by circuit 615. The conductive path through medium 630 between capacitors 112-113 and circuit 615 has a lower inductance and a lower resistance than the conductive path from the VRM to capacitors 112-113. The low impedance conductive path between capacitors 112-113 and circuit 615 through medium 630 allows capacitors 112-113 to provide a more constant supply voltage VCC to circuit 615.

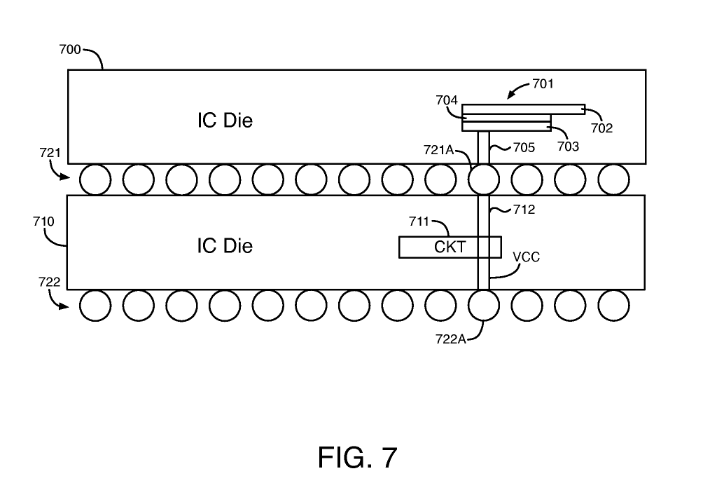

According other embodiments, an on-die decoupling capacitor in a first integrated circuit is coupled to a circuit in a second integrated circuit through a through-silicon via (TSV). The through-silicon via is in the second integrated circuit. The through-silicon via passes completely through the die of the second integrated circuit. A supply voltage is provided to the decoupling capacitor in the first integrated circuit and to the circuit in the second integrated circuit through the through-silicon via. In an embodiment, the first and second integrated circuits are in the same packaging house such as an organic package substrate, silicon interposer substrate, or multi-chip module (MCM). In an embodiment, the first and second integrated circuits are stacked vertically and coupled together through solder bumps. FIG. 7 illustrates an example of this embodiment.

FIG. 7 illustrates cross-sectional side views of two stacked integrated circuits that are coupled together through solder bumps, according to an embodiment of the present invention. FIG. 7 illustrates two separate integrated circuits (i.e., IC dies) 700 and 710. Integrated circuits 700 and 710 may be any types of integrated circuits. For example, integrated circuits 700 and 710 may be programmable integrated circuits, application specific integrated circuits, or a combination thereof. Integrated circuits 700 and 710 may include digital circuits, analog circuits, or both. Integrated circuits 700 and 710 may be the same type of integrated circuit or different types of integrated circuits.

Integrated circuits 700 and 710 are vertically stacked dies. Integrated circuits 700 and 710 are coupled together through solder bumps 721. Integrated circuit 710 is coupled to a package or interposer through solder bumps 722. Integrated circuit 710 includes a circuit 711 and a through-silicon via (TSV) 712. TSV 712 is filled with conductive material. TSV 712 passes completely through the die of integrated circuit 710. Circuit 711 may be, for example, a digital circuit, an analog circuit, or a passive circuit.

Integrated circuit 700 includes a via 705 and a decoupling capacitor 701. Decoupling capacitor 701 includes conductive regions 702-703 and a dielectric region 704. Conductive regions 702-703 form two conductive plates of the decoupling capacitor 701. Dielectric region 704 is in between conductive regions 702-703. Via 705 is filled with conductive material.

A supply voltage VCC is provided to integrated circuit 710 from an external VRM through solder bump 722A. The supply voltage VCC is provided through solder bump 722A and through the conductive material in TSV 712 to circuit 711. The supply voltage VCC is also provided through solder bump 722A, the conductive material in TSV 712, solder bump 721A, and the conductive material in via 705 to conductive region 703 of decoupling capacitor 701. The conductive path through vias 705 and 712 and bump 721A is a low impedance path. Decoupling capacitor 701 provides supply voltage current to circuit 711 through this low impedance path during the operation of circuit 711 to reduce variations in the supply voltage VCC received by circuit 711.

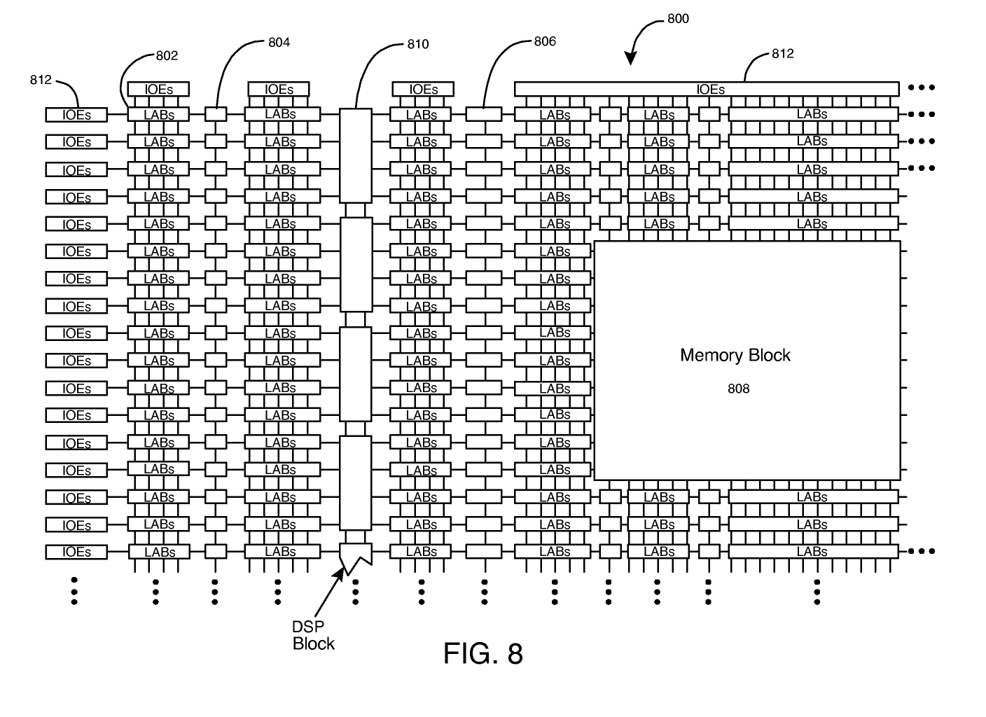

FIG. 8 is a simplified partial block diagram of a field programmable gate array (FPGA) 800 that can include embodiments of the present invention. FPGA 800 is merely one example of an integrated circuit that can include features of the present invention. It should be understood that embodiments of the present invention can be used in numerous types of integrated circuits such as field programmable gate arrays (FPGAs), programmable logic devices (PLDs), complex programmable logic devices (CPLDs), programmable logic arrays (PLAs), application specific integrated circuits (ASICs), memory integrated circuits, central processing units, microprocessors, analog integrated circuits, etc.

FPGA 800 includes a two-dimensional array of programmable logic array blocks (or LABs) 802 that are interconnected by a network of column and row interconnect conductors of varying length and speed. LABs 802 include multiple (e.g., 10) logic elements (or LEs).

A logic element (LE) is a programmable logic circuit block that provides for efficient implementation of user defined logic functions. An FPGA has numerous logic elements that can be configured to implement various combinatorial and sequential functions. The logic elements have access to a programmable interconnect structure. The programmable interconnect structure can be programmed to interconnect the logic elements in almost any desired configuration.

FPGA 800 also includes a distributed memory structure including random access memory (RAM) blocks of varying sizes provided throughout the array. The RAM blocks include, for example, blocks 804, blocks 806, and block 808. These memory blocks can also include shift registers and first-in-first-out (FIFO) buffers.

FPGA 800 further includes digital signal processing (DSP) blocks 810 that can implement, for example, multipliers with add or subtract features. Input/output elements (IOEs) 812 support numerous single-ended and differential input/output standards. IOEs 812 include input and output buffers that are coupled to pads of the integrated circuit 800. The pads are external terminals of the FPGA die. The pads are used to route, for example, input signals, output signals, and supply voltages between FPGA 800 and one or more external devices or other circuits in FPGA 800. FPGA 800 is an example of integrated circuit 100 shown in FIG. 1. According to this example, LABs 802 are in core areas 106-108, and IOEs 812 on the left and right sides of the die are in interface circuit areas 101 and 104, respectively. FPGA 800 is described herein for illustrative purposes. Embodiments of the present invention can be implemented in many different types of integrated circuits.

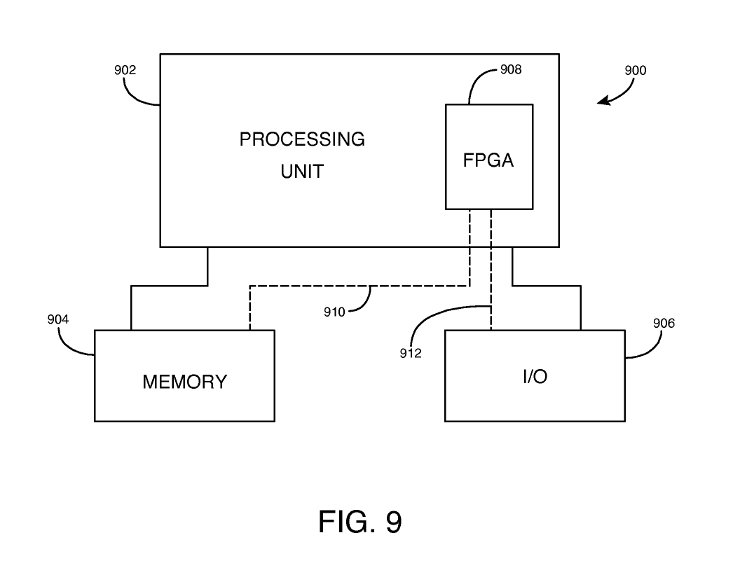

Embodiments of the present invention can also be implemented in a system that has an FPGA as one of several components. FIG. 9 shows a block diagram of an exemplary digital system 900 that can embody techniques of the present invention. System 900 can be a programmed digital computer system, digital signal processing system, specialized digital switching network, or other processing system. Moreover, such systems can be designed for a wide variety of applications such as telecommunications systems, automotive systems, control systems, consumer electronics, personal computers, Internet communications and networking, and others. Further, system 900 can be provided on a single board, on multiple boards, or within multiple enclosures.

System 900 includes a processing unit 902, a memory unit 904, and an input/output (I/O) unit 906 interconnected together by one or more buses. According to this exemplary embodiment, an FPGA 908 is embedded in processing unit 902. FPGA 908 can serve many different purposes within the system of FIG. 9. FPGA 908 can, for example, be a logical building block of processing unit 902, supporting its internal and external operations. FPGA 908 is programmed to implement the logical functions necessary to carry on its particular role in system operation. FPGA 908 can be specially coupled to memory 904 through connection 910 and to I/O unit 906 through connection 912.

Processing unit 902 can direct data to an appropriate system component for processing or storage, execute a program stored in memory 904, receive and transmit data via I/O unit 906, or other similar functions. Processing unit 902 can be a central processing unit (CPU), microprocessor, floating point coprocessor, graphics coprocessor, hardware controller, microcontroller, field programmable gate array programmed for use as a controller, network controller, or any type of processor or controller. Furthermore, in many embodiments, there is often no need for a CPU.

For example, instead of a CPU, one or more FPGAs 908 can control the logical operations of the system. As another example, FPGA 908 acts as a reconfigurable processor that can be reprogrammed as needed to handle a particular computing task. Alternatively, FPGA 908 can itself include an embedded microprocessor. Memory unit 904 can be a random access memory (RAM), read only memory (ROM), fixed or flexible disk media, flash memory, tape, or any other storage means, or any combination of these storage means.

The foregoing description of the exemplary embodiments of the present invention has been presented for the purposes of illustration and description. The foregoing description is not intended to be exhaustive or to limit the present invention to the examples disclosed herein. In some instances, features of the present invention can be employed without a corresponding use of other features as set forth. Many modifications, substitutions, and variations are possible in light of the above teachings, without departing from the scope of the present invention.

What is claimed is:

1. An integrated circuit comprising:
a first decoupling capacitor in the integrated circuit, wherein the first decoupling capacitor is coupled to a first external terminal of the integrated circuit; and
a first circuit in the integrated circuit, wherein the first circuit is coupled to a second external terminal of the integrated circuit, wherein the first decoupling capacitor is coupled to provide supply voltage current to the first circuit through the first and the second external terminals and through external conductors that are outside the integrated circuit.

2. The integrated circuit of claim 1, wherein the first circuit is an interface circuit, and wherein the first decoupling capacitor is located in a non-interface circuit area of the integrated circuit.

3. The integrated circuit of claim 1, wherein the external conductors are in a medium that is one of a package, an interposer, a redistribution layer, or another integrated circuit.

4. The integrated circuit of claim 3, wherein the medium is coupled to the integrated circuit through solder bumps, wherein the supply voltage current flows from the first decoupling capacitor to the first circuit through the external conductors and first and second ones of the solder bumps, and wherein the external conductors are coupled to the first and the second ones of the solder bumps.

5. The integrated circuit of claim 3, wherein a supply voltage is provided to the first decoupling capacitor and to the first circuit through the external conductors from a source that is outside of the integrated circuit and that is outside of the medium.

6. The integrated circuit of claim 1, further comprising:
a second decoupling capacitor in the integrated circuit, wherein the second decoupling capacitor is coupled to a third external terminal of the integrated circuit, and wherein the second decoupling capacitor is coupled to provide supply voltage current to the first circuit through the second and the third external terminals and through the external conductors.

7. The integrated circuit of claim 1, wherein the first decoupling capacitor comprises conductive islands in a first conductive layer of the integrated circuit that are coupled together through conductive material in vias and a conductive region in a second conductive layer of the integrated circuit.

8. The integrated circuit of claim 1, wherein an electrical connection is only formed between the first decoupling capacitor and the first circuit through conductors that are outside the integrated circuit, and wherein the first decoupling capacitor only provides the supply voltage current to the first circuit through the external conductors.

9. The integrated circuit of claim 1, wherein the first decoupling capacitor provides supply voltage current to a second circuit through the first external terminal and through the external conductors, and wherein the second circuit is located outside the integrated circuit.

10. A system comprising:
a first integrated circuit comprising a decoupling capacitor; and
a second integrated circuit comprising an internal circuit, wherein the first and the second integrated circuits are coupled together, and wherein the decoupling capacitor is coupled to the internal circuit through conductive material in a through-silicon via in the second integrated circuit.

11. The system of claim 10, wherein the first and the second integrated circuits are in the same packaging house.

12. The system of claim 10, further comprising:
solder bumps that are coupled to the first integrated circuit and to the second integrated circuit, wherein the decoupling capacitor is coupled to the internal circuit through at least one of the solder bumps, and wherein the first and the second integrated circuits are vertically stacked dies.

13. The system of claim 10, wherein the decoupling capacitor provides supply voltage current to the internal circuit for a supply voltage.

14. A method comprising:
providing a first decoupling capacitor in an integrated circuit, wherein the first decoupling capacitor is coupled to a first external terminal of the integrated circuit; and
providing a first circuit in the integrated circuit, wherein the first circuit is coupled to a second external terminal of the integrated circuit, wherein the first decoupling capacitor is coupled to provide supply voltage current to the first circuit through the first and the second external terminals and through external conductors that are outside the integrated circuit.

15. The method of claim 14, wherein the first circuit is an interface circuit, and wherein the first decoupling capacitor is in a non-interface circuit area of the integrated circuit.

16. The method of claim 14, wherein the external conductors are coupled to the integrated circuit through solder bumps, wherein the supply voltage current flows from the first decoupling capacitor to the first circuit through the external conductors and a subset of the solder bumps, and wherein the external conductors are coupled to the subset of the solder bumps.

17. The method of claim 14, wherein the external conductors are in a medium that is one of a package, an interposer, a redistribution layer, or another integrated circuit.

18. The method of claim 14, wherein an electrical connection is only formed between the first decoupling capacitor and the first circuit using conductors that are outside the integrated circuit, and wherein the first decoupling capacitor only provides the supply voltage current to the first circuit through the external conductors.

19. The method of claim 14, further comprising:
providing a second decoupling capacitor in the integrated circuit, wherein the second decoupling capacitor is coupled to a third external terminal of the integrated circuit, and wherein the second decoupling capacitor is coupled to provide supply voltage current to the first circuit through the second and the third external terminals and through the external conductors.

20. The method of claim 14, wherein the first decoupling capacitor provides supply voltage current to a second circuit through the first external terminal and through the external conductors, and wherein the second circuit is located outside the integrated circuit.
